(19) United States
(12) Patent Application Publication
(10) Pub. No.: US 2012/0186852 A1
(43) Pub. Date: Jul. 26, 2012

(54) Structure of electrolessly palladium and gold plated films and process for making the same, assembled structure of palladium and gold plated films bonded with copper or copper-palladium wire and assembling process therefore

(75) Inventors: Ming-Hung Lin, Taoyuan County (TW); Tasi-Tung Kuo, Taoyuan County (TW); Kuan-Cheng Liu, Taoyuan County (TW); Ying-Chien Lee, Taoyuan County (TW); Kuo-Pin Chiu, Taoyuan County (TW)

(73) Assignee: Taiwan Uyemura Co., Ltd., Taoyuan County (TW)

(21) Appl. No.: 13/326,370

(22) Filed: Dec. 15, 2011

(30) Foreign Application Priority Data
Jan. 25, 2011 (TW) 100102660
Jan. 25, 2011 (TW) 100102661

(51) Int. Cl. B21D 39/00; B23K 1/20; H01B 5/00; H05K 3/00

(52) U.S. Cl. 174/126.2; 428/621; 427/97.1; 228/180.5

(57) ABSTRACT

Disclosed is a structure of electrolessly palladium (Pd) and gold (Au) plated films on a bonding pad, comprising a Pd plated layer on the bonding pad; and an Au plated layer on the Pd plated layer. Also disclosed is an assembled structure formed of the electrolessly Pd—Au plated films wire-bonded with a copper (Cu) or Pd—Cu wire to the Au plated layer. In addition, a process for producing the structure of the electrolessly Pd—Au plated films and an assembling process for the assembled structure are disclosed. According to the present invention, the Pd plated layer is used to replace the conventional nickel layer so as to enhance the wire-bonding strength between the Cu or Pd—Cu wire and the bonding pad.

### FIELD OF THE INVENTION

The invention relates to a protective layer for the surface of a bonding pad, in particular, to a protective layer formed of electrolessly palladium (Pd) and gold (Au) plated films. In addition, the invention also relates to an assembling process and an assembled structure, in particular, to an assembling process and an assembled structure with a copper (Cu) or Pd—Cu wire.

### BACKGROUND OF THE INVENTION

In the processes for assembling electronic parts such as wafers, liquid crystal display (LCD) substrates, ceramic substrates, aluminum substrates, IC substrates and printed circuit boards, it is necessary to form electrolessly nickel (Ni) and Au plated films on the surface of the bonding pad, which provides electrical connections, so as to improve the bondability between the bonding wires and the bonding pads as well as the resistance to corrosion. Upon the formation of the Au layer through electroless Au-plating after the formation of the Ni layer on the bonding pad, the displacement reaction of Ni for Au makes the particles at the grain boundary of the Ni layer incur sever selective attack and thereby leads to the formation of corrosion voids below the Au layer and accordingly, makes the Ni layer brittle relatively. As a result, sufficient bonding strength cannot be obtained after the welding operation.

Thereafter, electroless Ni—Pd—Au plating processes are provided to eliminate the severe attack by Au on the Ni layer. Though the aforesaid electroless plating processes can solve the problem, however, the presence of the Ni layer increases the hardness of the resulting films and thereby makes it hard to carry out the subsequent wire-bonding of Cu or Pd—Cu wires smoothly.

For overcoming the disadvantages mentioned above, the invention provides a novel structure of electrolessly Pd—Au plated films, a process for making the same, an assembled structure of Pd—Au plated films bonded with Cu or Pd—Cu wires and an assembling process therefor.

### SUMMARY OF THE INVENTION

One object of the invention is to provide a novel structure of electrolessly Pd—Au plated films and a process for making the same, which are useful in the manufacture of lower level electronic products with higher density of integrated circuits.

Another object of the invention is to provide a structure of electrolessly Pd—Au plated films and a process for making the same wherein no Ni layer is present.

At the same time, the reliability in the bonding between the Cu or Pd—Cu wire and the bonding pad can be increased with less cost.

A further object of the invention is to provide an assembled structure of the above-mentioned structure of electrolessly Pd—Au plated films bonded with Cu or Pd—Cu wires and an assembling process therefor wherein no Ni layer is present. At the same time, the reliability in the bonding between the Cu or Pd—Cu wire and the bonding pad can be increased with less cost.

A further object of the invention is to provide an assembling process for bonding Cu or Pd—Cu wires and a structure obtained therefrom, which are useful in the manufacture of lower level electronic products with higher density of integrated circuits.

A further object of the invention is to provide a novel and operable surface treatment for assembled products bonded with Cu or Pd—Cu wires.

For achieving the objects mentioned above, the invention provides a structure of electrolessly Pd—Au plated films on a bonding pad, comprising a Pd plated layer on the bonding pad; and an Au plated layer on the Pd plated layer.

The invention also provides a process for producing electrolessly Pd—Au plated films, comprising providing a bonding pad, forming a Pd plated layer on the bonding pad; and forming an Au plated layer on the Pd plated layer. Preferably, the Pd plated layer is a displacement-type Pd plated layer formed through a displacement reaction on the bonding pad. More preferably, a reduction-type Pd plated layer is further formed on the displacement-type Pd plated layer through a reduction reaction. Preferably, the Au plated layer is formed on the Pd plated layer through a displacement-, reduction- or half-displacement-half-reduction-type reaction (hereinafter simply referred to as a “mixed-type” reaction).

The invention also provides a process for producing electrolessly Pd—Au plated films, comprising providing a bonding pad, forming a Pd plated layer on the bonding pad through simultaneous displacement and reduction reactions with a solution having effects of forming Pd in both a catalysis manner and an electroless manner; and forming an Au plated layer on the Pd plated layer through a displacement-, reduction- or “mixed-type” reaction.

The invention also provides an assembled structure of the above-mentioned structure of electrolessly Pd—Au plated films bonded with a Cu or Pd—Cu wire, comprising a bonding pad, a Pd plated layer on the bonding pad; an Au plated layer on the Pd plated layer; and a Cu or Pd—Cu wire bonded to the Au plated layer.

The invention provides an assembling process with a Cu or Pd—Cu wire, comprising providing a bonding pad, forming a Pd plated layer on the bonding pad; forming an Au plated layer on the Pd plated layer; and wire-bonding a Cu or Pd—Cu wirebonding to the Au plated layer.

In the above-mentioned structures or processes, the Pd plated layer can be formed through a displacement reaction, a two-stage reaction of displacement and reduction reactions, or a reaction through the use of a single solution capable of effecting a displacement reaction and a reduction reaction at the same time.

The objects, technical contents and features of and the effects achieved by the invention are further elucidated in details through the description of the following embodiments and examples.

In the description, unless otherwise noted, all amounts including quantities, percentages, portions, and proportions, are understood to be modified by the word “about”, and amounts are not intended to indicate significant digits.

Unless otherwise noted, the articles “a”, “an”, and “the” mean “one or more” and the terms “comprise” and “comprising” have open-ended meanings in general and do not exclude additional, unrecited components or elements.

### Embodiments for Carrying Out the Invention

The invention discloses a structure of electrolessly Pd—Au plated films and a process for making the same, which involve surface-treating a bonding pad intended for use in the assembling process with Cu or Pd—Cu wires. The aforesaid bonding pad is preferably made of Cu. Thereafter, a highly dense Pd plated layer and an Au plated layer are formed in sequence on the surface of the bonding pad. The wire-bonding strength of the Cu or Pd—Cu wires bonded in a later step can be increased without the use of a Ni layer.

The Pd plated layer can be formed through an electrochemical reaction. The Pd plated layer can be a material made of pure Pd or Pd—P (phosphorous) alloy. The structure of electrolessly Pd—Au plated films according to the invention can be formed by, for example, the following three processes.

Referring to FIG. 1, a flowchart of the steps for carrying out the first process is shown. According to step S1, a bonding pad 10 is firstly provided. Then, according to step S2, a displacement-type Pd plated layer 12 is formed on the surface of the bonding pad 10 through a displacement reaction, and a reduction-type Pd plated layer 14 is formed, for increasing the total thickness, on the displacement-type Pd plated layer 12 through a reduction reaction as shown in step S3. Finally, according to step S4, an Au plated layer 16 is formed to cover the reduction-type Pd plated layer 14 through a displacement-, reduction- or mixed-type reaction. A structure as shown in FIG. 2 is thus formed.

In the embodiment described above, the total thickness of the displacement-type Pd plated layer 12 and the reduction-type Pd plated layer 14 is 0.03-0.2 μm, and also 0.03-0.07 μm, preferably 0.06-0.12 μm, and also preferably 0.09-0.2 μm; and the thickness of the Au plated layer 16 is 0.03-0.2 μm, and also 0,03-0.07 μm, preferably 0.06-0.12 μm, and also preferably 0.09-0.2 μm.

Referring to FIG. 3, a flowchart of the steps for carrying out the second process is shown. According to step S1, a bonding pad 10 is firstly provided. Then, according to step S12, a Pd plated layer 18 is formed on the bonding pad using a single solution having effects of forming Pd in both a catalytic and an electroless manners such that a displacement reaction and a reduction reaction both are effected at the same time. Finally, according to step S13, an Au plated layer 16 is formed on the Pd plated layer 18 through a displacement-, reduction- or mixed-type reaction. A structure as shown in FIG. 4 is thus formed.

In the embodiment described above, the thickness of the Pd plated layer is 0.03-0.2 μm, and also 0.03-0.07 μm, preferably 0.06-0.12 μm, and also preferably 0.09-0.2 μm; and the thickness of the Au plated layer is 0.03-0.2 μm, and also 0.03-0.07 μm, preferably 0.06-0.12 μm, and also preferably 0.09-0.2 μm.

Referring to FIG. 5, a flowchart of the steps for carrying out the third process is shown. As compared with the first process described above, the third process is a simplified one with the omission of step S3 for the formation of the reduction-type Pd plated layer. The third process comprises the steps of providing a bonding pad 10 (step S1), then forming a displacement-type Pd plated layer 12 on the surface of the bonding pad 10 through a displacement reaction (step S2), and finally forming an Au plated layer 16 to cover the displacement-type Pd plated layer 12 through a displacement-, reduction- or mixed-type reaction (step S23). A structure as shown in FIG. 6 is thus formed.

In the embodiment described above, the thickness of the displacement-type Pd plated layer 12 is 0.03-0.2 μm, and also 0.03-0.07 μm, preferably 0.06-0.12 μm, and also preferably 0.09-0.2 μm; and the thickness of the Au plated layer 16 is 0.03-0.2 μm, and also 0.03-0.07 μm, preferably 0.06-0.12 min, and also preferably 0.09-0.2 μm.

Each of the steps for carrying out the three processes described above can be operated at a temperature in a range of from about 25° C. to about 95° C. and a pH in a range of from about 4 to about 9.

As shown in FIGS. 2, 4 and 6, it is clear that the structures of electrolessly Pd—Au plated films according to the invention comprise a bonding pad (10), a Pd plated layer (12, optionally 14, or 18) on the bonding pad; and an Au plated layer (16) on the Pd plated layer. FIG. 7 schematically shows an assembled structure with the bonding of a Cu or Pd—Cu wire. As shown in FIG. 7, according to the invention, an assembled structure 30 comprises a bonding pad 10 which can be Cu, a Pd plated layer 20 on and in close contact with the bonding pad 10; an Au plated layer 16 on and in close contact with the Pd plated layer 20; and a Cu or Pd—Cu wire 32 bonded to the Au plated layer 16 for being electrically connected with the bonding pad 10.

In the embodiments described above, the thickness of the Pd plated layer 20 is 0.03-0.2 μm, and also 0.03-0.07 μm, preferably 0.06-0.12 μm, and also preferably 0.09-0.2 μm; and the thickness of the Au plated layer 16 is 0.03-0.2 μm, and also 0.03-0.07 μm, preferably 0.06-0.12 μm, and also preferably 0.09-0.2 μm.

In the producing processes, the invention involves surface-treating the bonding pad 10 intended for use in the assembling process with Cu or Pd—Cu wires so as to form, directly on the surface of the bonding pad 10, a highly dense Pd plated layer 20 and an Au plated layer 16 in sequence. The wire-bonding strength of the Cu or Pd—Cu wires 32 bonded to the Au plated layer 16 is increased without Ni layer.

Each of the steps for forming the Pd plated layer 20 and the Au plated layer 16 according to the invention can be operated at a temperature in a range of from about 25° C. to about 95° C. and a pH in a range of from about 4 to about 9.

According to the invention, the process for assembling the Cu or Pd—Cu wires 32 can be categorized into three types as follows, depending on the processes for forming the Pd plated layer 20.

Referring to FIG. 8, a flowchart of the steps for carrying out the first assembling process is shown. The first assembling process comprises steps S1, S2, S3 and S4 for producing electrolessly Pd—Au plated films and a step S5 for wire-bonding a Cu or Pd—Cu wire 32 to the Au plated layer 16 on the bonding pad 10. A structure as shown in FIG. 9 is thus formed.

In the embodiment, the Pd plated layer 20 is a combination of the displacement-type Pd plated layer 12 and the reduction-type Pd plated layer 14.

Referring to FIG. 10, a flowchart of the steps for carrying out the second assembling process is shown. The second assembling process comprises steps S1, S12 and S13 for producing electrolessly Pd—Au plated films and a step S14 for wire-bonding a Cu or Pd—Cu wire 32 to the Au plated layer 16 on the bonding pad 10. A structure as shown in FIG. 11 is thus formed.

Referring to FIG. 12, a flowchart of the steps for carrying out the third assembling process is shown. The third assembling process comprises steps S1, S2 and S23 for producing electrolessly Pd—Au plated films and a step S24 for wire-bonding a Cu or Pd—Cu wire 32 to the Au plated layer 16 on the bonding pad 10. A structure as shown in FIG. 13 is thus formed.

According to the invention, a Pd plated layer is used to replace Ni layer to avoid various problems caused by the Ni layer. The invention provides a novel and operable surface treatment for assembled products where Pd—Au plated films are bonded with Cu or Pd—Cu wires. In addition, the technique according to the invention is, as one of the best modes, useful in the assembling process for producing lower level electronic products with higher density of integrated circuits. The reason is that for the said lower level electronic products, the number of reflow needed is small, leading to less diffusion of Cu atoms and in turn less diffusion of Cu atoms into the Pd plated layer. Further, due to the reduction in volume of the elements reduced and the increase in circuit density, the bonding pads are reduced in volume, for which the invention can fulfill the requirements. Also, the feature according to the invention of eliminating the use of Ni layer not only can facilitate the wire-bonding of Cu or Pd—Cu wires to the Cu bonding pads without adversely affecting the reliability but also can reduce the cost.

The preferred embodiments and examples described above are merely the illustrations of the invention and are not intended to be interpreted as limitations to the invention. All the equivalents, variations and modifications which are not apart from the spirit and scope of the inventive concept should fall within the scope of the claims attached.

### BRIEF DESCRIPTION OF THE DRAWINGS

FIG. 1 is a flowchart of the steps for carrying out the first process for producing electrolessly Pd—Au plated films according to the invention.

FIG. 2 schematically shows a structure of electrolessly Pd—Au plated films produced by the steps depicted in FIG. 1.

FIG. 3 is a flowchart of the steps for carrying out the second process for producing electrolessly Pd—Au plated films according to the invention.

FIG. 4 schematically shows a structure of electrolessly Pd—Au plated films produced by the steps depicted in FIG. 3.

FIG. 5 is a flowchart of the steps for carrying out the third process for producing electrolessly Pd—Au plated films according to the invention.

FIG. 6 schematically shows a structure of electrolessly Pd—Au plated films produced by the steps depicted in FIG. 5.

FIG. 7 schematically shows an assembled structure of Cu or Pd—Cu wire.

FIG. 8 is a flowchart of the steps for carrying out the first process for assembling Cu or Pd—Cu wire according to the invention.

FIG. 9 schematically shows an assembled structure of Cu or Pd—Cu wire produced by the steps depicted in FIG. 8.

FIG. 10 is a flowchart of the steps for carrying out the second process for assembling Cu or Pd—Cu wire according to the invention.

FIG. 11 schematically shows an assembled structure of Cu or Pd—Cu wire produced by the steps depicted in FIG. 10.

FIG. 12 is a flowchart of the steps for carrying out the third process for assembling Cu or Pd—Cu wire according to the invention.

FIG. 13 schematically shows an assembled structure of Cu or Pd—Cu wire produced by the steps depicted in FIG. 12.

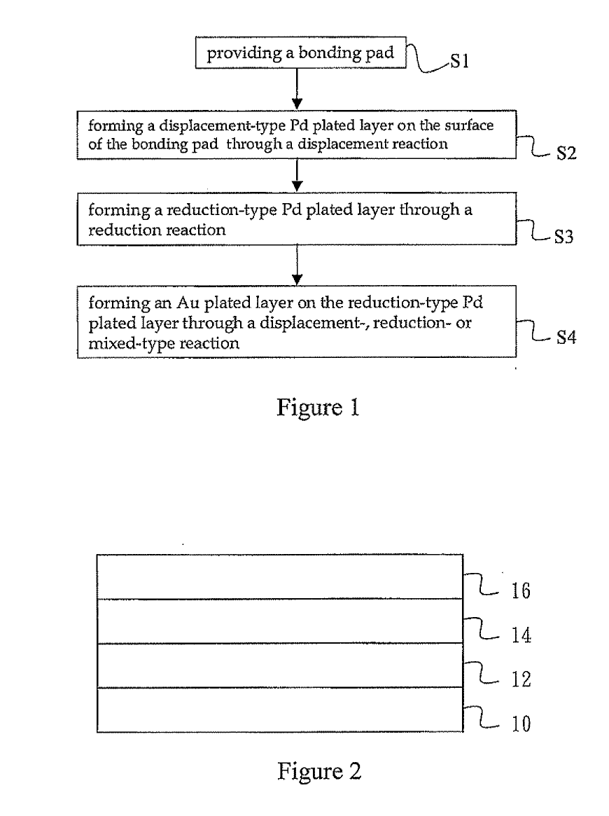

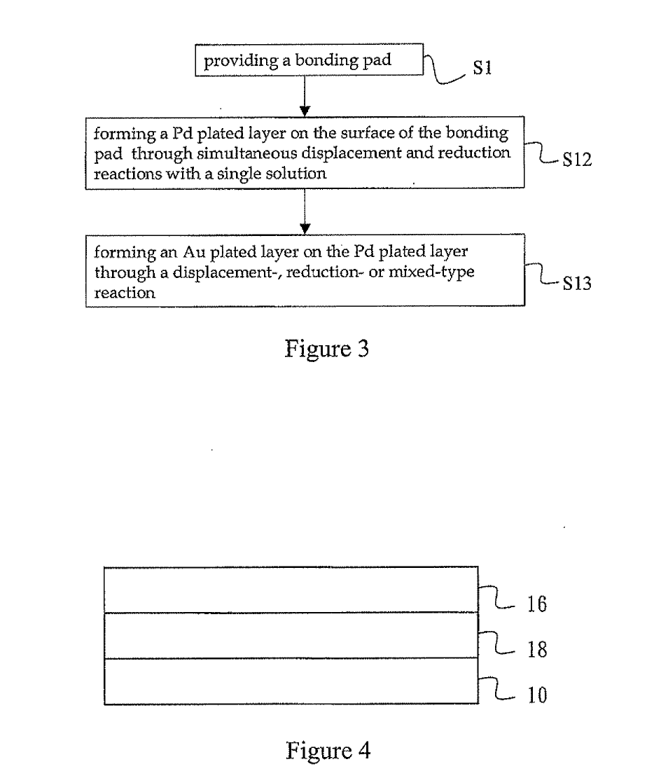

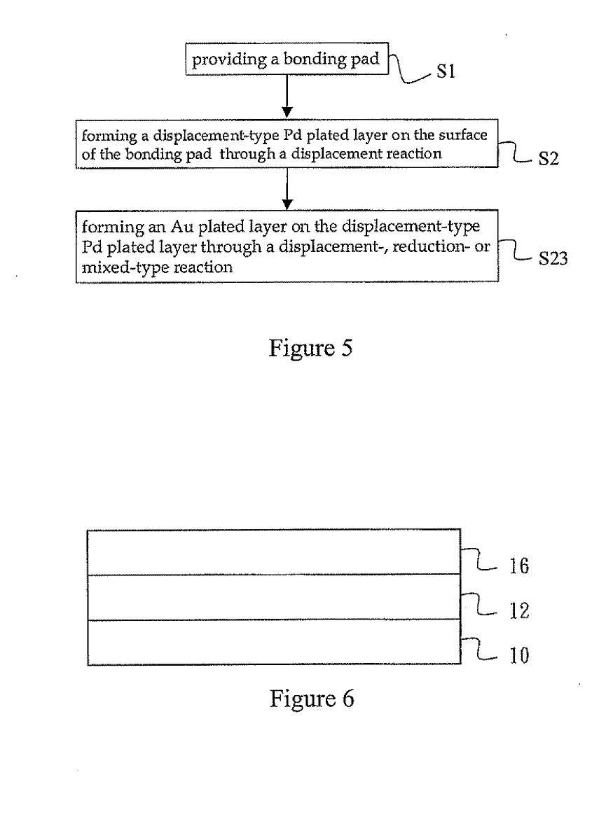

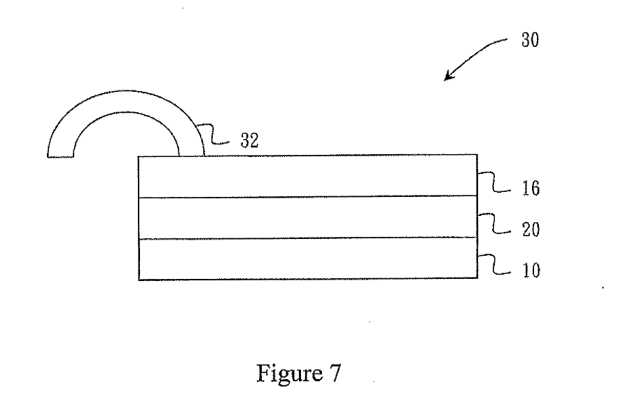

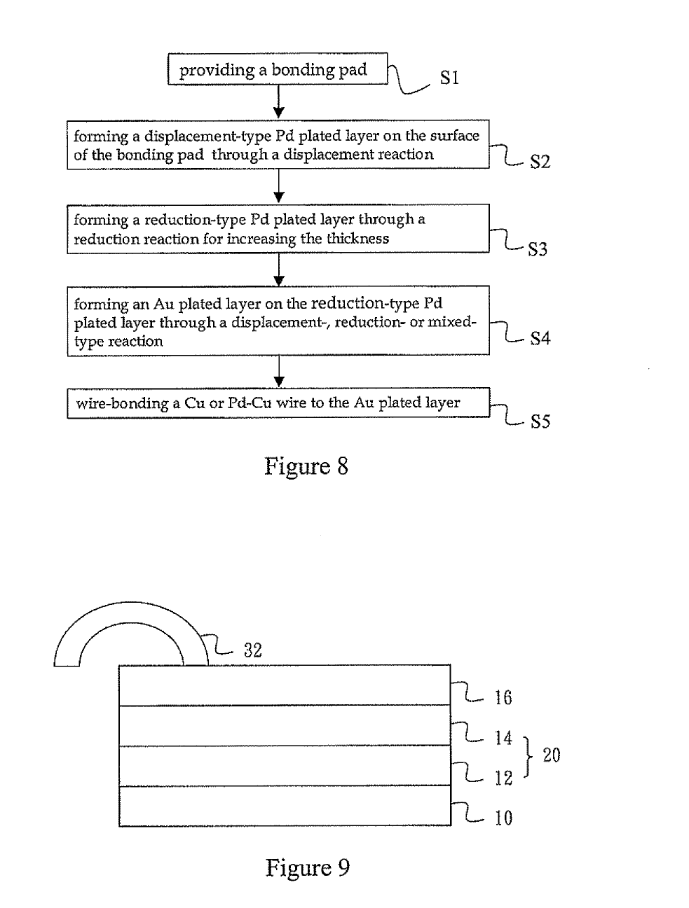

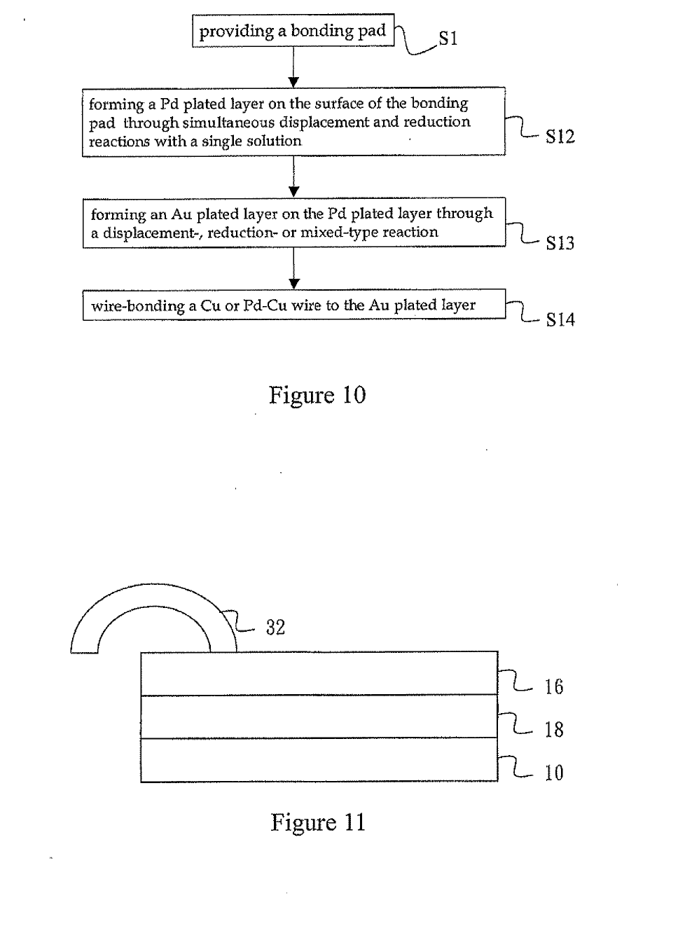

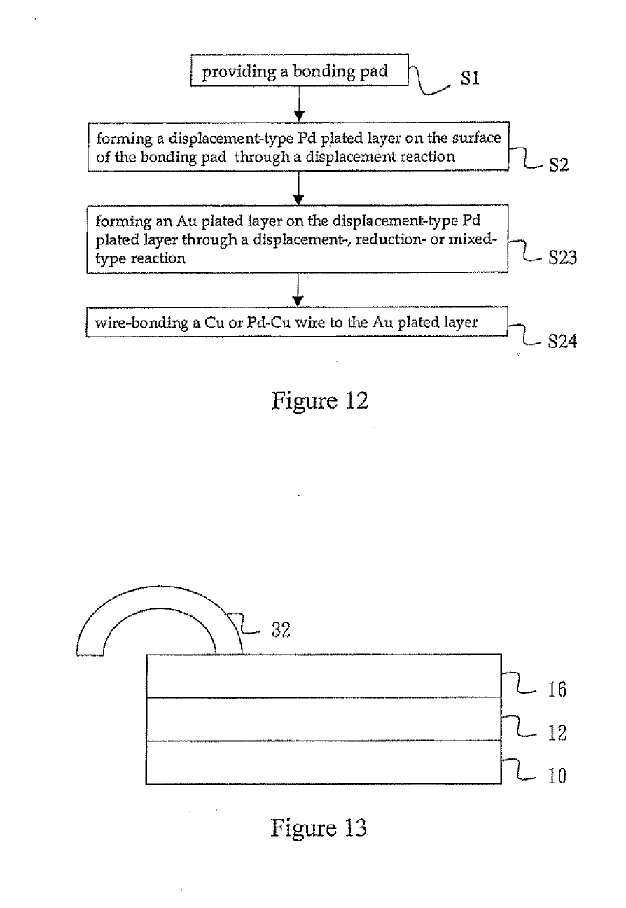

### LIST OF THE REFERENCE NUMERALS

10 a bonding pad

12 a displacement-type Pd plated layer

14 a reduction-type Pd plated layer

16 an Au plated layer

18 a displacement-type/reduction-type Pd plated layer

20 a Pd plated layer

30 an assembled structure

32 a Cu or Pd—Cu wire

What is claimed is:

1. A structure of electrolessly Pd—Au plated films on a bonding pad, comprising
a Pd plated layer on the bonding pad; and
an Au plated layer on the Pd plated layer.

2. The structure of electrolessly Pd—Au plated films according to claim 1, wherein the Pd plated layer is formed through a displacement reaction or through a displacement reaction and a reduction reaction; and the Au plated layer is formed through a displacement-, reduction- or mixed-type reaction.

3. A process for producing electrolessly Pd—Au plated films, comprising the steps of
providing a bonding pad;
forming a displacement-type Pd plated layer on the bonding pad through a displacement reaction; and
forming an Au plated layer on the Pd plated layer through a displacement-, reduction- or mixed-type reaction,

4. The process according to claim 3, wherein the bonding pad is a material of Cu;
and the displacement-type Pd plated layer is a material of pure Pd or Pd—P

5. The process according to claim 3, which is carried out at a temperature in a range of from 25° C. to 95° C. and a pH in a range of from 4 to 9.

6. The process according to claim 3, wherein the displacement-type Pd plated layer has a thickness in a range of from 0.03 μm to 0.2 μm, and the Au plated layer has a thickness in a range of from 0.03 μm to 0.2 μm.

7. The process according to claim 3, which is useful in the process for assembling lower level electronic products with higher density of integrated circuits.

8. The process according to claim 3, which, prior to the formation of the Au plated layer, further comprises a step of forming a reduction-type Pd plated layer on the displacement-type Pd plated layer through a reduction reaction.

9. The process according to claim 8, wherein the displacement-type Pd plated layer and the reduction-type Pd plated layer have a total thickness in a range of from 0.03 μm to 0.2 μm, and the Au plated layer has a thickness in a range of from 0.03 gm to 0.2 μm.

10. A process for producing electrolessly Pd—Au plated films, comprising the steps of
providing a bonding pad;
forming a Pd plated layer on the bonding pad through simultaneous displacement and reduction reactions with a solution having effects of forming Pd in both a catalytic manner and an electroless manner; and
forming an Au plated layer on the Pd plated layer through a displacement-, reduction- or mixed-type reaction.

11. The process according to claim 10, wherein the bonding pad is a material of Cu;
and the Pd plated layer is a material of pure Pd or Pd—P alloy.

12. The process according to claim 10, which is carried out at a temperature in a range of from 25° C. to 95° C. and a pH in a range of from 4 to 9.

13. The process according to claim 10, wherein the Pd plated layer has a thickness in a range of from 0.03 μm to 0.2 μm, and the Au plated layer has a thickness in a range of from 0.03 μm to 0.2 μm.

14. The process according to claim 10, which is useful in the process for assembling lower level electronic products with higher density of integrated circuits.

15. An assembled structure with a Cu or Pd—Cu wire comprising
a bonding pad;
a Pd plated layer on the bonding pad;
an Au plated layer on the Pd plated layer; and
a Cu or Pd—Cu wire wire-bonded to the Au plated layer.

16. The assembled structure according to claim 15, wherein the bonding pad is a material of Cu; and the Pd plated layer is a material of pure Pd or Pd—P alloy.

17. The assembled structure according to claim 15, wherein the Pd plated layer comprises a displacement-type Pd plated layer and a reduction-type Pd plated layer.

18. The assembled structure according to claim 15, wherein the Pd plated layer has a thickness in a range of from 0.03 μm to 0.2 μm, and the Au plated layer has a thickness in a range of from 0.03 μm to 0.2 μm.

19. An assembling process with a Cu or Pd—Cu wire, comprising the steps of providing a bonding pad;
forming a Pd plated layer on the bonding pad;
forming an Au plated layer on the Pd plated layer; and
wire-bonding a Cu or Pd—Cu wire to the Au plated layer.

20. The process according to claim 19, wherein the step of forming a Pd plated
layer on the bonding pad comprises
firstly forming a displacement-type Pd plated layer on the bonding pad through a displacement reaction; and then
forming a reduction-type Pd plated layer on the displacement-type Pd plated layer through a reduction reaction.

21. The process according to claim 19, wherein the bonding pad is a material of Cu;
and the Pd plated layer is a material of pure Pd or Pd—P alloy.

22. The process according to claim 19, wherein the steps of forming a Pd plated layer and forming an Au plated layer are carried out at a temperature in a range of from 25° C. to 95° C. and a pH in a range of from 4 to 9.

23. The process according to claim 19, wherein the Pd plated layer has a thickness in a range of from 0.03 μm to 0.2 μm, and the Au plated layer has a thickness in a range of from 0.03 μm to 0.2 μm.

24. The process according to claim 19, wherein the step of forming a Pd plated layer on the bonding pad is carried out through simultaneous displacement and reduction reactions with a solution having effects of forming Pd in both a catalysis manner and an electroless manner.

25. The process according to claim 19, wherein the Au plated layer is formed through a displacement-, reduction- or mixed-type reaction.

26. The process according to claim 19, wherein the Pd plated layer is formed on the bonding pad through a displacement reaction.
